(19) United States
(12) Patent Application Publication
(10) Pub. No.: US 2007/0194342 A1
(43) Pub. Date: Aug. 23, 2007

(54) GaN SEMICONDUCTOR DEVICE AND PROCESS EMPLOYING GaN ON THIN SAPHIRE LAYER ON POLYCRYSTALLINE SILICON CARBIDE

(76) Inventor: Daniel M. Kinzer, El Segundo, CA (US)

Correspondence Address: OSTROLENK FABER GERB & SOFFEN, 1180 AVENUE OF THE AMERICAS, NEW YORK, NY, 100368403, US

(21) Appl. No.: 11/622,162

(22) Filed: Jan. 11, 2007

Related U.S. Application Data
(60) Provisional application No. 60/758,328, filed on Jan. 12, 2006.

(51) Int. Cl. H01L 33/00

(52) U.S. Cl. 257/103

(57) ABSTRACT

A substrate for a GaN based semiconductor device is formed by a poly SiC substrate having a thin sapphire layer on the top surface thereof Sapphire layer may be 0.1 to 1.0 microns thick. GaN type layers are then grown atop the sapphire layer with a transition layer between them if desired.

### RELATED APPLICATION

This application claims the benefit of U.S. Provisional Application No. 60/758,328, filed Jan. 12, 2006, the entire disclosure of which is incorporated by reference herein.

### FIELD OF THE INVENTION

This invention relates to semiconductor devices and more specifically relates to a novel structure and process for the manufacture of semiconductor devices.

### BACKGROUND OF THE INVENTION

In order to manufacture effective GaN based semiconductor devices, a relatively thick GaN layer, for example, 6 microns, is needed. However, thick GaN layers are difficult to produce economically.

Silicon is a desirable and economical substrate for such devices. However, it is difficult to grow thick layers or films of GaN type material on a silicon substrate because of thermal and lattice mismatch. Further, it is difficult to obtain a high blocking voltage through the film due to defects and the relatively high conductivity through the silicon substrate. Still further, the thermal properties of silicon substrates are not optimal, silicon having a medium thermal resistance.

GaN or Al GaN on sapphire substrates have somewhat better crystal properties, but have severe thermal limitations.

GaN growth on monocrystalline silicon carbide (SiC) allows growth of thicker GaN film with less lattice mismatch and excellent thermal characteristics but the SiC substrate is expensive and SiC wafers are available in only small diameters.

Polycrystalline SiC as a substrate is inexpensive and has good thermal characteristics but it is highly conductive and cannot be used as a template for high quality GaN growth.

Silicon on insulator (SOI) has been proposed, bonded to silicon carbide to isolate the substrate and provide a template for GaN film growth. However, this requires two bonding steps and the conductive silicon template has a large lattice mismatch to the GaN film.

### SUMMARY OF THE INVENTION

In accordance with the invention, a thin film or wafer, for example, 0.1 to 1.0 micrometers thick, of sapphire is bonded to a polycrystalline SiC substrate. The sapphire layer then provides an excellent substrate for film growth, to form a III-nitride heterjunction device, for example, an AlN, AlGaN and GaN layered film.

This combination provides the following advantages:
1. The polycrystalline SiC substrate is inexpensive.
2. The very thin sapphire layer provides a good template (non-conductive, and close lattice match) for GaN layers.
3. The polycrystalline SiC has a high thermal conductivity.
4. Both sapphire and polycrystalline silicon carbide are available with diameters up to 150 mm.
5. The sapphire layer or wafer can be cleaved in process similar to an SOI process, leaving only a thin film of sapphire on the poly SiC wafer, with the sapphire substrate being used many times to form many wafer templates for initial AlN growth.

### BRIEF DESCRIPTION OF THE DRAWINGS

FIG. 1 shows a cross-section of a polysilicon SiC substrate with a thin sapphire layer bonded thereto.

FIG. 2 shows the starting wafer of FIG. 1 with a series of an AlN buffer, an AlGaN layer, and a GaN layer deposited thereon.

FIG. 3 shows the wafer of FIG. 2 after the formation of source, drain and gate contacts thereon.

### DETAILED DESCRIPTION OF THE DRAWINGS

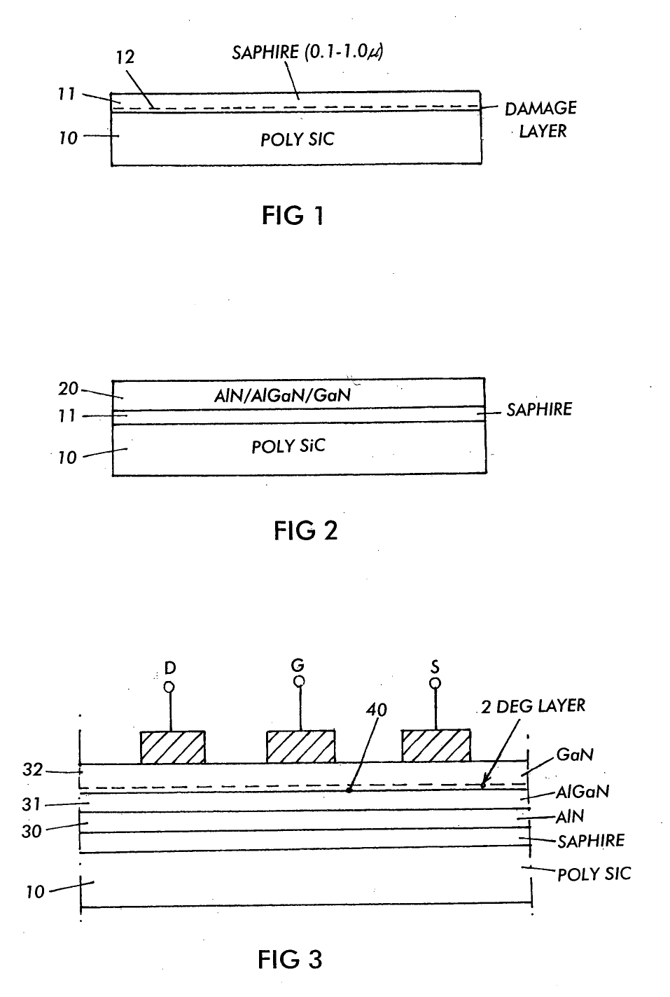

Referring first to FIG. 1, there is shown a polysiliconcarbide substrate 10 of any desired thickness and diameter (or surface area). A thin (most likely in the range of 0.1-1 um thick) sapphire layer is formed by bonding a sapphire wafer to the SiC wafer. The sapphire wafer has been prepared so that a thin film of sapphire may be cleaved from the bulk of the sapphire to remain atop SiC substrate layer 10. This can be done with a damage layer 11 in the sapphire wafer, as by implantation or other means, on the plane where the wafer is intended to be cleaved. This then serves as a substrate for the growth of a III-nitride heretojunction or GaN based device.

Thus, as shown in FIG. 2, a series of layers 20, which may be an AlN transition layer, an AlGaN layer and a relatively thick GaN layer are grown on sapphire layer 11.

The wafer of FIG. 2 may then be conventionally completed with standard metallizing and dicing process as well known.

Thus, as shown in FIG. 3, the AlN transition layer 30, AlGaN layer 31 and GaN layer 32 are more conventionally shown. Any other desired transition layer can be used, of any desired thickness.

A conventional 2DEG layer 40 is formed between the AlGaN layer 31 and GaN layer 32.

A contact metal layer is conventionally formed atop the surface of GaN layer 32 and is etched or otherwise separated into segments 50, 51 and 52, forming drain, gate and source electrodes, respectively.

Although the present invention has been described in relation to particular embodiments thereof, many other variations and modifications and other uses will become apparent to those skilled in the art. It is preferred, therefore, that the present invention be limited not by the specific disclosure herein.

What is claimed is:

1. A substrate for a GaN based semiconductor device; said substrate comprising a polycrystalline silicon carbide wafer having parallel top and bottom surfaces of given thickness, and a thin sapphire layer atop said top surface of said polycrystalline silicon carbide substrate; the top surface of said sapphire layer adapted to receive the layers of a GaN based device having a relatively thick GaN layer.

2. The substrate of claim 1, wherein said sapphire layer has a thickness greater than about 0.1 microns.

3. The substrate of claim 1, wherein said sapphire layer has a thickness of between about 0.1 microns and 1.0 microns.

4. A GaN type semiconductor device comprising a poly SiC substrate having an upper flat surface; a thin sapphire layer atop and in contact with said upper flat surface; a transition layer atop the surface of said sapphire layer; an AlGaN layer atop and in contact with said transition layer; a GaN layer atop and in contact with said AlGaN layer and said GaN layer; and spaced source, drain and gate contacts atop aid GaN layer.

5. The device of claim 4, wherein said sapphire layer has a thickness greater than about 0.1 micron.

6. The device of claim 4, wherein said sapphire layer has a thickness of from about 0.1 microns to about 1.0 microns.

7. The process of manufacture of a III-nitride heterojunction device comprising the steps of forming a thin layer of sapphire atop a poly SiC substrate, and thereafter depositing a plurality of nitride-containing layers atop said sapphire to define a 2DEG layer and a thick GaN layer, and thereafter depositing conductive electrodes atop said thick GaN layer.

8. The process of claim 7, wherein said sapphire layer has a thickness which is less than that of said Poly SiC substrate and is greater than about 0.1 micron and less than about 1.0 micron.
